(19) United States
(12) Patent Application Publication
(10) Pub. No.: US 2023/0274858 A1
(43) Pub. Date: Aug. 31, 2023

(54) SUPERCONDUCTOR WIRE INCLUDING SUPERCONDUCTOR TAPE STRANDS AND A SUPERCONDUCTOR CABLE INCLUDING SUPERCONDUCTING WIRES

(71) Applicant: AMPeers LLC, Houston, TX (US)

(72) Inventors: Janakiram Kaushal KADIYALA, Kakinada (IN); Eduard Galstyan, Houston, TX (US)

(21) Appl. No.: 18/173,978

(22) Filed: Feb. 24, 2023

Related U.S. Application Data
(60) Provisional application No. 63/268,530, filed on Feb. 25, 2022.

(51) Int. Cl. H01B 12/06; H10N 60/85

(52) U.S. Cl. CPC H01B 12/06; H10N 60/857

(57) ABSTRACT

A superconductor wire can achieve a Jₑ of at least 600 A/mm² at 4.2 K, 20 T applied magnetic field, which is greater than Jₑ previously reported in the literature. The superconductor wire can include superconductor tape stands that have I_{c} per total strand width of at least 125 A/mm at 4.2 K, 20 T applied magnetic field. In an embodiment, the superconductor wire can have superconductor film with a modified REBCO composition, where (Ba+M)/Cu is at least 0.72. In the same or different embodiment, the superconductor film can have a thickness of at least 3 microns. The superconductor tape strands can have a stabilizer layer, where the thickness of the stabilizer is selected so that the neutral plane of the strands is near or passes through the superconductor film. A superconductor cable can be made from superconductor wires.

### CROSS REFERENCE TO RELATED APPLICATION

This application claims priority under 35 U.S.C. § 119(e) to U.S. Patent Application No. 63/268,530 entitled “Superconductor Wire Including Superconductor Tape Strands and a Superconductor Cable Including Superconducting Wires,” by Kadiyala et al., filed Feb. 25, 2022, which is assigned to the current assignee hereof and incorporated herein by reference in its entirety.

### GOVERNMENT LICENSE RIGHTS

This invention was made with government support under contract number DE-SC0020717 awarded by the US Department of Energy. The government has certain rights in the invention.

### FIELD OF THE DISCLOSURE

The present disclosure relates to superconductor wires and cables, and more particularly to, superconducting wires that include superconductor tape strands and cables that include superconductor wires.

### RELATED ART

A Low Temperature Superconductor (LTS) material can include a metal alloy or a metal compound, such as Nb—Ti, Nb₃Sn, or the like. Such materials are ductile and can be drawn in the form of wires. The LTS material requires cooling with liquid He, is limited by its relatively low maximum magnetic field that it can achieve, and is not well suited for power applications where alternating current (AC) losses can impose a severe cryogenic burden.

A High Temperature Superconductor (HTS) material can operate at relatively higher temperatures (at 77 K), at higher magnetic fields, or both higher temperatures and higher magnetic fields as compared to an LTS material. Thus, an HTS material can address challenges with using LTS in magnets for particle accelerators, fusion energy systems, proton-beam and carbon-beam therapy systems, and coils for electric power devices. However, not all HTS materials can be used in such applications. For example, Ba₂Sr₂CaCu₂O₈ (Bi-2212) can be drawn into a wire; however, Bi-2212 wires have weak mechanical properties and support a moderate, not high engineering current density (Jₑ). Jₑ refers to the critical current of the HTS wire divided by the overall cross-sectional area of the HTS wire before the application of electrically insulation media, such as epoxies and polymers. Further, Bi-2212 requires a delicate heat treatment that may be performed using O₂ at 900° C.

Rare Earth-Barium-Copper-Oxide (REBCO) can be a HTS material and can be used in the form of tapes. The tapes can be more challenging to achieve shapes or other geometries that are more easily achieved with wires made with an LTS material or Bi-2212. To address the issues with using tapes, multi-strand REBCO cable configurations have been made, and such cable configurations can include Roebel cables in a rectangular structure, twisted stacked tape cables (TSTC), and conductor-on-round-core (CORC®-brand) cables/wires. Such HTS wires/cables do not meet the stringent bend radius requirement for magnets being developed for particular applications. For instance, none of these wires/cables has been demonstrated for high Jₑ in high magnetic fields at a bend radius of 15 mm. New designs for HTS wires and cables are needed to allow such magnets to be achieved.

### BRIEF DESCRIPTION OF THE DRAWINGS

Embodiments are illustrated by way of example and are not limited in the accompanying figures.

FIG. 1 includes an illustration of a side view of a superconductor wire in straight form with a magnetic field applied in a direction perpendicular to the length of the superconductor wire.

FIG. 2 includes an illustration of a top view of a superconductor wire at a bend radius with a magnetic field applied in a direction perpendicular to a tangent at the midpoint of the curve.

FIG. 3 includes a flow chart for a process of forming a superconductor tape strand.

FIG. 4 includes an illustration of a cross-sectional view of a portion of a workpiece that includes a substrate and a buffer stack.

FIG. 5 includes an illustration of a cross-sectional view of the workpiece of FIG. 4 after forming a superconductor film over the buffer stack.

FIG. 6 includes a photograph of a portion of a workpiece that includes a substrate, a buffer stack, and a superconductor film showing bowing of the workpiece.

FIG. 7 includes an illustration of a cross-sectional view of the workpiece of FIG. 5 after forming a metal layer over the superconductor film.

FIG. 8 includes an illustration of a cross-sectional view of the workpiece of FIG. 7 after forming a protective layer over the metal layer.

FIG. 9 includes an illustration of a cross-sectional view of a portion of a superconductor tape strand formed from the workpiece of FIG. 8 after thinning the substrate, removing the protective layer, slitting the workpiece into superconductor tape strands and forming a metal layer along exposed surfaces of the strand.

FIG. 10 includes an illustration of a cross-sectional view of the superconductor tape strand of FIG. 9 after forming a stabilizer layer along exposed surfaces of the strand.

FIG. 11 includes a flow chart for a process of forming a superconductor wire and a superconductor cable.

FIG. 12 includes a photograph of an enlarged cross-sectional view of a superconductor wire including a wire former and superconductor tape strands.

FIG. 13 includes a photograph of a side view of the superconductor wire of FIG. 12.

FIG. 14 includes an illustration of a cross-sectional view of the superconductor wire of FIG. 12 after forming a protective coating around the superconductor tape strands and wire former.

FIG. 15 includes an illustration of a cross-sectional view of a portion of a superconductor cable that includes superconductor wires wrapped around a cable former.

FIG. 16 includes an illustration of a cross-sectional view of the superconductor cable after forming a protective coating around the superconductor wires and the cable former.

FIG. 17 includes a photograph of a superconductor wire at a bend radius of 15 mm.

FIG. 18 includes a plot of current-voltage characteristics of the superconductor wire of FIG. 17 at 77 K and an applied magnetic field of 0 T.

FIG. 19 includes a plot of lift factor in critical current as a function of applied magnetic field for superconductor tape strands used in the superconductor wire in FIG. 17.

FIG. 20 includes a plot of current-voltage characteristics of the superconductor wire of FIG. 17 at 4.2 K and an applied magnetic field of 30 T.

FIG. 21 includes photographs of a superconductor wire when tested in straight form and at a bend radius of 15 mm.

FIG. 22 includes plots of current-voltage characteristics when the superconductor wire of FIG. 21 was tested in straight form and at a bend radius of 15 mm.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

The term “cable” is intended to mean a structure made up of a plurality of wires twisted around a central axis with or without a cable former.

The term “conductor diameter” with respect to a superconductor wire that includes superconductor tape strands, is intended to mean a diameter defined by outermost superconductor strand or strands of the superconductor wire when viewed in cross section. In an embodiment with a wire former, the conductor diameter is determined by the wire former and superconductor tape strands. The conductor diameter is not defined by a perimeter of a protective coating, such as an electrically insulating media, that surrounds the superconductor tape strands and wire former.

Regarding dimensions, a superconductor tape strand has a length, a width, and a thickness, where length<width<thickness.

The term “rare earth” or “rare earth element” is intended to mean Y, Sc, and the Lanthanides (La to Lu) in the Periodic Table of the Elements.

Group numbers correspond to columns within the Periodic Table of Elements based on the IUPAC Periodic Table of Elements, version dated Dec. 1, 2018.

The terms “on,” “overlying,” and “over” may be used to indicate that two or more physical objects are in direct physical contact with each other. However, “over” may also mean that two or more objects are not in direct contact with each other. For example, “over” may mean that one object is above another object, but the objects do not contact each other and may have another object or objects in between the two objects.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

The use of the word “about,” “approximately,” or “substantially” is intended to mean that a value of a parameter is close to a stated value or position. However, minor differences may prevent the values or positions from being exactly as stated. Thus, differences of up to ten percent (10%) for the value are reasonable differences from the ideal goal of exactly as described.

The term “significantly different” is intended to mean that a value of a variable (e.g., length, width, etc.) is greater than ten percent (10%) (and more than twenty percent (20%) for impurity concentrations) as compared to a different value of the same variable.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the superconductor arts.

Superconductor wires can achieve high engineering current density, Jₑ, values that have not been previously achieved. The superconductor wires include superconductor tape strands where the superconductor tape stands include superconductor film having a modified REBCO composition and a thickness of at least 3.0 microns. The architecture of the superconductor tape strands can have a thickness of a stabilizer layer that is selected so that a neutral plane of the superconductor strands is close to or within the superconductor film. Such superconductor tape strands are wrapped around a wire former to form a superconductor wire that can achieve high critical current, I_{c} per total strand width and Jₑ that have not been previously achieved for particular sets of temperature and applied magnetic field conditions.

In an aspect, a superconductor wire can include a first superconductor tape strand and a second superconductor tape strand. Each of the first superconductor tape strand and the second superconductor tape strand can include a substrate, a buffer stack, a superconductor film, a metal layer, and a stabilizer layer, wherein the metal layer is disposed between the superconductor film and the stabilizer layer. The superconductor wire can have a conductor diameter no greater than 4 mm, and the superconductor wire can exhibit an engineering current density of at least 600 A/mm² when at a temperature of 4.2 K and exposed to an applied magnetic field of 20 T.

In another aspect, a superconductor wire can include a first superconductor tape strand and a second superconductor tape strand. Each of the first superconductor tape strand and the second superconductor tape strand can include a substrate, a buffer stack, a superconductor film, a metal layer, and a stabilizer layer, wherein the metal layer is disposed between the superconductor film and the stabilizer layer. The superconductor wire can exhibit an engineering current density of at least 800 A/mm² when at a temperature of 4.2 K and exposed to an applied magnetic field of 20 T.

In yet another aspect, a superconductor wire can include a first superconductor tape strand and a second superconductor tape strand. Each of the first superconductor tape strand and the second superconductor tape strand can includes a substrate, a buffer stack, a superconductor film, a metal layer, and a stabilizer layer, wherein the metal layer is disposed between the superconductor film and the stabilizer layer. The superconductor wire can exhibit a critical current of at least 125 A/mm of total width of superconductor tape strands when at a temperature of 4.2 K and exposed to an applied magnetic field of 20 T.

In a further aspect, a superconductor wire can include a first superconductor tape strand and a second superconductor tape strand. Each of the first superconductor tape strand and the second superconductor tape strand can include a substrate; a superconductor film having a thickness of at least 3 microns and including Ba, Cu, and M, wherein M is Hf, Zr, Sn, or a combination thereof, and on an atomic basis, within the superconductor film, (Ba+M)/Cu is greater than 0.72; and a stabilizer layer, wherein the superconductor film is disposed between the substrate and the stabilizer layer.

In another aspect, a process can include forming a superconductor film over a substrate, wherein the substrate has a first side and a second side opposite the first side, and the superconductor film is closer to the first side than to the second side. The superconductor film can have a thickness of at least 3 microns and includes Ba, Cu, and M, wherein M is Hf, Zr, Sn, or a combination thereof, and on an atomic basis, within the superconductor film, (Ba+M)/Cu is greater than 0.72. The process further includes forming a protective layer over the superconductor film; etching the substrate to reduce a thickness of the substrate; removing the protective layer after removing the portion of the substrate; and forming a stabilizer layer over the superconductor film to form a superconductor tape strand.

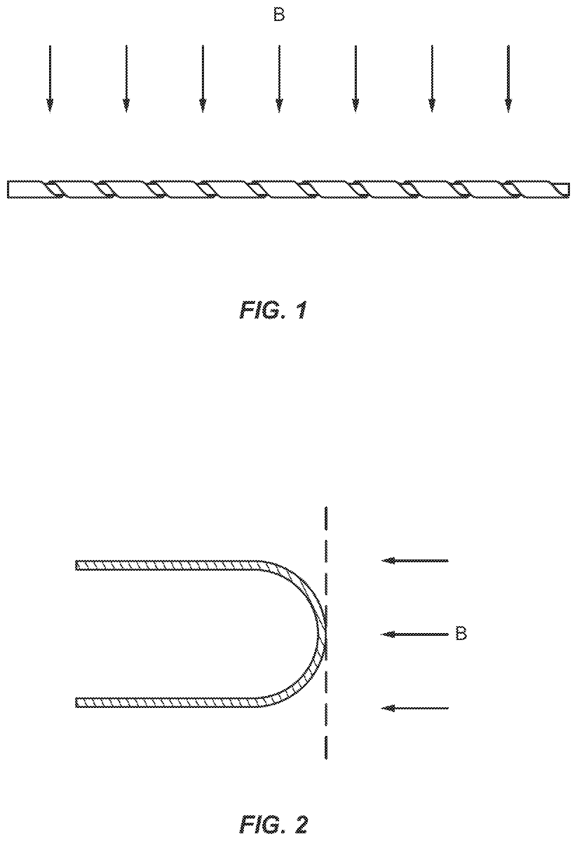

A superconductor wire can be exposed to an applied magnetic field while current is passing through the wire. For a flat superconductor film, the magnetic field may be applied parallel or perpendicular to the superconductor film. In a superconductor wire, superconductor tape strands can be helically wrapped along a wire former. Thus, the applied magnetic field can reach the superconductor film at many angles, even if the magnetic field is applied in a single direction. In FIG. 1, the superconductor wire is in straight form and has a length that lies along a direction in the x-y plane. The magnetic field, B, is applied in the z-plane and perpendicular to the x-y plane. In FIG. 2, the superconductor wire is bent. When the wire is bent, the magnetic field, B, is applied perpendicular to a tangent (dashed line in FIG. 2) at the midpoint along the radius of the curve. To reduce the risk of ambiguity, when a superconductor wire is in straight form, an applied magnetic field means that the magnetic field is applied perpendicular to the length of the superconductor wire, and when the superconductor wire is bent into a curve, an applied magnetic field means that the magnetic field is applied perpendicular to a tangent at the midpoint along the radius of the curve. Many of the values for electrical parameters described below can be achieved when the superconductor wire is in a straight form and when the superconductor wire is at a bend radius, such as a bend radius of 15 mm.

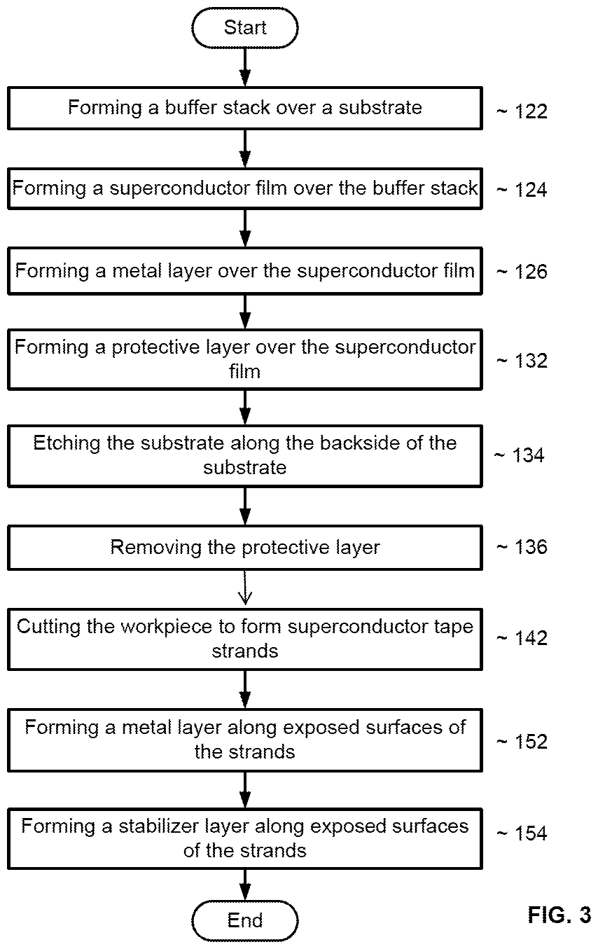

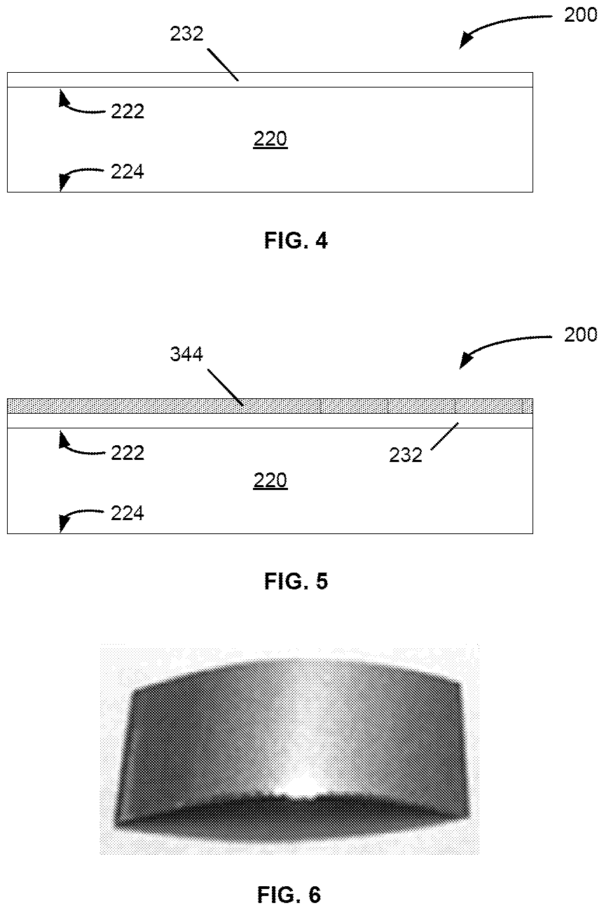

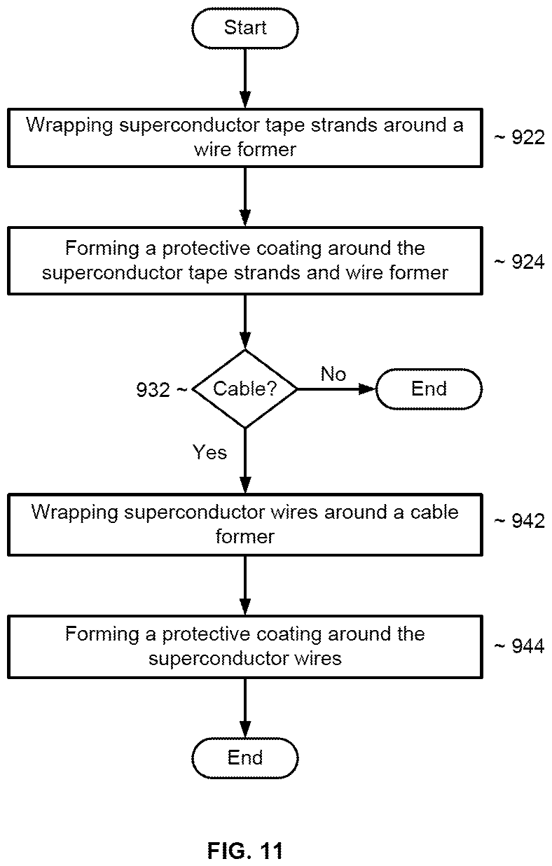

Processes of forming superconductor wires and superconductor cables are described. FIG. 3 includes a flow chart for a process that can be used to form superconductor tape strands. FIG. 11 includes a flow chart for processes to form a superconductor wire using superconductor tape strands and to form a superconductor cable from superconductor wires. FIGS. 4 to 10 correspond the process described with respect to FIG. 3, and FIGS. 12 to 16 correspond to the processes described with respect to FIG. 11. Thus, the formation of superconductor tape strands is described before describing the formation of a superconductor wire and a superconductor cable.

The process can include forming a buffer stack over a substrate at block 122 of FIG. 3. FIG. 4 includes a cross-sectional view of a portion of a workpiece 200 that includes a substrate 220 and a buffer stack 232 over the substrate 220. The substrate has a major surface 222 closer to the buffer stack 232 and a major surface 224 farther from the buffer stack 232 and opposite the major surface 222. The substrate 220 can include a nickel alloy. The nickel alloy can be a Hastelloy®-brand alloy available from Haynes Stellite Company, Kokomo, Ind., US; an Inconel®-brand alloy or a Monel®-brand alloy, both available from Huntington Alloys Corporation of Huntington, W. Va., US; stainless steel; or another suitable Ni alloy. The thickness of the substrate 220 can be in a range of 30 microns to 70 microns.

The buffer stack 232 allows a subsequently-formed superconductor film to be properly formed. The buffer stack 232 includes at least one film that is biaxially textured. The buffer stack can include MgO, LaMnO₃, CeO₂, Gd₂Zr₂O₇, yttria-stabilized zirconia, SrTiO₃, or a combinations thereof. An exemplary buffer stack 232 can include, starting with the film closest to the substrate 220 to the film farthest from the substrate, amorphous Al₂O₃/Y₂O₃/IBAD MgO/Y₂O₃/homo-epitaxial MgO/LaMnO₃, where IBAD is ion-beam-assisted deposition. Each of the deposited films within the buffer stack 232 can have a thickness in a range from 5 nm to 200 nm. The buffer stack 232 can have a thickness in a range from 0.1 micron to 2 microns.

The process can further include forming a superconductor film over the buffer stack at block 124 of FIG. 3. FIG. 5 includes a cross-sectional view of a portion of a workpiece 200 after forming a superconductor film 344 over the buffer stack 232. The superconductor film 344 includes an HTS material. For example, the superconductor film 344 can be a Rare Earth-Barium-Copper-Oxide that is also an HTS material and is herein referred to as “REBCO.” For example, REBCO can be RE₁Ba₂Cu₃O_{7-δ}, where RE is Y, Gd, Sm, Nd, Eu, Dy, Ho, Yb, Er, Tm, Lu, or a combination thereof, and 0.1≤δ≤0.5.

In an embodiment, the superconductor film 344 includes REBCO that has nanoscale defects. Such defects can form when REBCO includes a BaMO₃, where M is Zr, Hf, Sn, or a combination thereof. The superconductor film 344 can include a REBCO phase that includes the HTS material and a BaMO₃ phase. On an atomic basis, within the superconductor film 344, (Ba+M)/Cu is at least 0.72 and can be in a range from 0.72 to 0.85. On a mole basis, M can be 0.5 mol % to 25 mol % of superconductor film 344.

The superconductor film 344 has a thickness of at least 3.0 microns or at least 4.0 microns. Such a thickness for the superconductor film 344, along with the nanocrystal defects, allows Jₑ and I_{c} per total strand width of superconductor tape to be significantly greater than in conventional superconducting wires. In an embodiment, the superconductor film 344 has a range of 3.0 microns to 6.0 microns. The superconductor film 344 can be formed by deposition using metalorganic chemical vapor deposition (MOCVD), pulsed laser deposition, electron-beam evaporation, or metal organic deposition.

The improved performance seen with a superconductor wire including the superconductor film 344 comes with a consequence. FIG. 6 includes a photograph of a portion of a workpiece that includes a substrate, which is made of a Hastelloy®-brand alloy, having a thickness of 50 microns and a REBCO superconductor film having a thickness of 4 microns and (Ba+M)/Cu of at least 0.72. In FIG. 6, the superconductor film is visible, and the workpiece has a bowed shape across its 12 mm dimension. In layman's terms, the shape of the workpiece is similar to a cross-sectional shape of a metal tape seen with a mechanical, retractable tape measure found in a hardware store. Such a bowed shape is not well suited for wrapping the workpiece around a wire former to form a superconductor wire. A portion of the substrate 220 can be removed to reduce or eliminate the bowing.

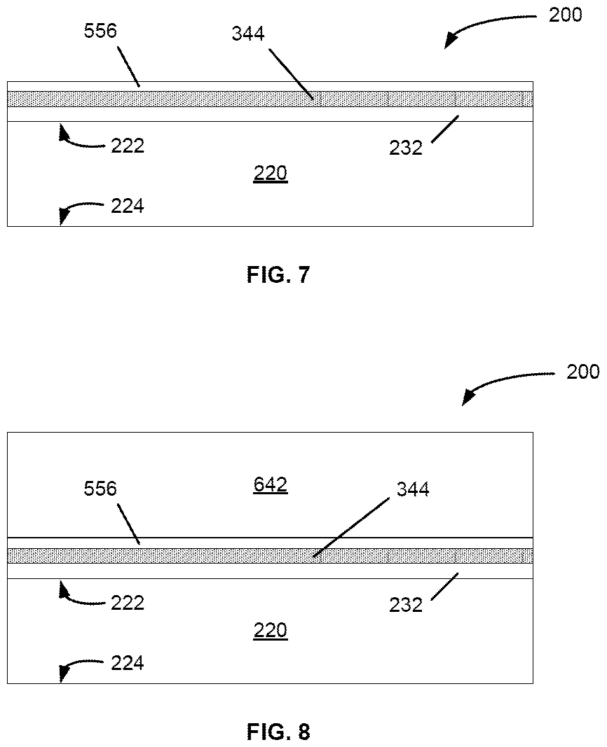

The process includes forming a metal layer over the superconductor film at block 126 of FIG. 3. FIG. 7 includes a cross-sectional view of the workpiece 200 after a metal layer 556 is formed over the superconductor film 344. The metal layer 556 protects the superconductor film 344 when a portion of the substrate 220 is subsequently removed. The metal layer 556 can include Ag or a noble metal, such as Au, Pt, Pd, or the like. The metal layer 556 has a thickness sufficient to be continuous along the superconductor film 344. In an embodiment, the metal layer 556 is a Ag layer. In the same or different embodiment, the metal layer 556 can have a thickness of 0.1 micron to 2.0 microns. In an embodiment, the metal layer 556 is optional and not used.

The process includes forming a protective layer over the superconductor film at block 132 of FIG. 3. FIG. 8 includes a cross-section of the workpiece 200 after forming a protective layer 642 over the superconductor film 344. If the metal layer 556 is not present, the protective layer 642 can be formed on the superconductor film 344. The protective layer 642 is along the side of the workpiece 200 opposite the substrate 220. The protective layer 642 includes a material that can later be removed without damaging the workpiece, and the superconductor film 344 in particular. The protective layer 642 can be in the form of a tape that includes a tape substrate and a pressure sensitive adhesive. An exemplary tape can include a Kapton®-brand tape available from DuPont Electronics, Inc. of Wilmington, Del., USA. Alternatively, the protective layer 642 can include a polymer, such as polyimide, a polyester, a phenolic resin, or the like that is coated onto the workpiece 200. When the protective layer 642 is coated, the protective layer 642 can be hard baked to reduce the amount of solvent and may help to cross-link a polymer precursor within the protective layer 642.

The process further includes etching the substrate along the backside of the substrate at block 134 in FIG. 3. Removing a portion of the substrate 220 reduces or eliminates the amount of bowing as seen in FIG. 6. The removal is performed so that the thickness of the substrate 220 remains substantially uniform between the center and edges of the substrate 220. Residual oxide along the exposed surface of the substrate 220 can be removed to allow for more uniform removal of the substrate 220. Etching can be performed to remove a portion of the substrate 220. Wet chemical or isotropic dry etching may be performed to remove the portion of the substrate 220. A dilute, aqueous solution including CuSO₄, HNO₃, HCl, or a carboxylic acid, for example, CH₃COOH, may be used.

After etching, the substrate 220 can have a thickness in a range from 10 microns to 25 microns. The thickness allows for good tolerance to bending strain that can occur when wrapping superconductor tape strands around a wire former when forming a superconductor wire.

The process further includes removing the protective layer 642 at block 136 in FIG. 3. The protective layer 642 can be removed by exposing the protective layer 642 to a very low temperature, for example, −100° C. or lower. The very low temperature can cause the protective layer 642 to debond from the underlying layer and allows the protective layer 642 to be peeled away from the workpiece 200. Alternatively, the protective layer 642 can be removed using in a solvent or oxidizing the protective layer 642, for example, plasma ashing the protective layer 642.

The process includes slitting the workpiece to form superconductor tape strands at block 142 in FIG. 3. The workpiece 200 can have length and width dimensions that are each 10 mm or more. Slitting is performed to form strands that have widths in a range from 1 mm to 3 mm. A width outside of the range described may be used if needed or desired for a particular application. Slitting can be performed using a mechanical or laser slitting tool. The laser slitting tool is well suited to slit thin substrates.

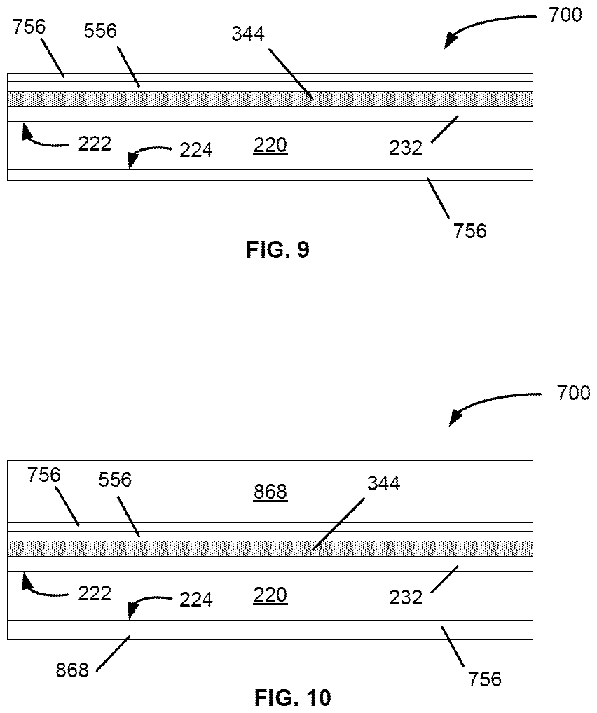

The process further includes forming a metal layer along exposed surfaces of the strands at block 152 of FIG. 3. FIG. 9 includes a cross-sectional view of a superconductor tape strand 700 after a metal layer 756 is formed along exposed surfaces of the strand 700. The metal layer 756 can be formed along sides of the strands 700 to protect sides of the superconductor film 344. The metal layer 756 can include any of the materials as previously described with respect to the metal layer 556. When both metal layers 556 and 756 are present, the metal layers 556 and 756 can have the same composition or different compositions. The metal layer 756 can have different thicknesses along different surfaces of the workpiece. The thickness of the metal layers 556 and 756 over the superconductor film 344 is greater than the thickness of the metal layer 756 along the substrate 220. In the same or different embodiment, the metal layers 556 and 756 have a combined thickness of 0.5 micron to 8.0 microns along the superconductor-side of the workpiece 200 and the metal layer 756 has a thickness of 0.2 micron to 3.0 microns along the major surface 224 of the substrate 220.

The process further includes forming a stabilizer layer along exposed surfaces of the superconductor tape strands at block 154 in FIG. 3. FIG. 10 includes a cross-sectional view of the strand 700 after a stabilizer layer 868 is formed along exposed surfaces of the superconductor tape strand 700. The thickness of the stabilizer layer 868 can be selected so that the superconductor tape strand 700 has an architecture where the superconductor film 344 is positioned near the neutral plane of the strand. The neutral plane is the plane where the strain within the workpiece 200 is 0, that is, not compressive and not tensile. Such a tape architecture can be achieved by a strategic selection of the thickness of the stabilizer layer 868 to reduce the distance between the superconductor film 344 and the neutral plane of the tape, which reduces bending strain when superconductor tape strands are bent into small diameters.

The stabilizer layer 868 can include a material having a resistivity at 20° C. of at most 10 μΩ·cm. An exemplary material includes Cu, Ag, Au, Ni, Al, W, or Zn. The selection of material can affect how the material is deposited. For example, Cu, Ag, Au, and Ni are well suited for plating. When plating, the pH of the plating solution should be selected so that the plated material is not too brittle or too soft. In an embodiment, Cu can be plated using a particular plating solution having a pH in a range of 2.0 to 2.6. The pH may depend on the material being plated and the composition of the plating solution. Empirical data can be collected to determine a desire pH range for a particular plating solution composition and material to be placed. All of the exemplary materials described can be sputter deposited.

The thickness of the stabilizer layer 868 along the superconductor-side of the strand can be selected to achieve a high critical current retention, I_{c} retention, when tested in the form of a wrapped superconductor wire. I_{c} retention is the percentage of I_{c} at 77 K and an applied magnetic field of 0 T (i.e., no applied magnetic field) when a superconductor wire is bent divided by I_{c} at 77 K and an applied magnetic field of 0 T when a superconductor wire is in straight form, or (I_{c} at 77 K, 0 T)_{bent}/(I_{c} at 77° K, 0 T)_{straight}×100%. For the same superconductor wire, different bend radii may have different values of I_{c} retention. Unless expressly stated to the contrary herein, I_{c} retention values are at a bend radius of 15 mm.

The wrapped superconductor wire can include a wire former having diameter in a range from 0.5 mm to 1.1 mm. Typically, the wire former has a diameter in a range from 0.7 mm to 0.85 mm. Generally, the widths of the superconductor tape strands are at least 1.5 times the conductor diameter when the tape is wound. Thus, the layers of strands closer to the wire former will have relatively narrower widths because the conductor diameter is smaller when such closer layers are wound, and layers of strands farther to the wire former will have relatively wider widths because the conductor diameter is larger when such farther layers are wound.

I_{c} retention at a bend radius of 15 mm is at least 70%, at least 80%, or at least 90%. I_{c} retention at a bend radius of 15 mm of 95% has been achieved, and higher I_{c} retention at a bend radius of 15 mm higher than 95% may be achieved.

Empirical data can be generated to provide a table that can provide thickness information for the stabilizer layer 868. For example, sets of experimental strands can be formed, where each set has a different thickness of the substrate 220. Before forming the stabilizer layer 868, all other layers and films within the stands have substantially the same composition and thicknesses. Within each set of strands having substantially the same substrate thickness, different thicknesses of the stabilizer layer 868 are formed along the superconductor-side of the strands. When the strands are at the operating conditions (e.g., temperature and magnetic field), current flowing through the strands can be measured to determine I_{c} retention. The procedure can be repeated for the other sets of other sets of substrates 220.

A production lot of strands can have substantially the same thickness of the substrates 220. Such thickness of the substrates 220 is matched to the closest thickness of substrate 220 for the sets of experimental strands. After the particular set of experimental strands is identified, a thickness for the stabilizer layer 868 can be selected, where the thickness of the stabilizer layer 868 corresponds to the highest I_{c} retention achieved by a particular experimental strand within the set of experimental strands for a particular bend radius, such as a bend radius of 15 mm.

The material composition of the substrate 220 or any other layer or film may affect the location of the neutral plane within the superconductor tape strand 700. The empirical data previously described may have generated from experimental strands where each strand has a Hastelloy®-brand alloy substrate and a Cu stabilizer layer. Other empirical data can be generated for a different material for the substrate 220 or any other layer or film within the strand. For example, new empirical data can be generated for a particular composition of a stainless steel substrate or a Ag or Au stabilizer layer. The procedure used to generate the new empirical data is the same as previously described. The procedure for selecting a thickness of the Ag or Au stabilizer layer is substantially the same as selecting the thickness for the Cu stabilizer layer previously described.

In another embodiment, the empirical data from experiments can be used to build a simulator program. Inputs may include the material of the substrate 220, the thickness of the substrate 220, and the material of the stabilizer layer 868. The simulator program can use simple bending to determine the location of the neutral plane of the strand 700 as the thickness of the stabilizer layer 868 is varied. Simple bending refers to bending about one axis. The output from the simulator program can be a recommended thickness for the stabilizer layer 868, where the thickness of the stabilizer layer 868 corresponds to the neutral plane within the superconductor tape strand 700 being within or close to the superconductor film 344.

In practice, the stabilizer layer 868 can have a thickness along the superconductor-side of the superconductor tape strand 700 in a range from 5 microns to 80 microns or from 12 microns to 50 microns. In the same or different embodiment, along the substrate-side of the superconductor tape strand 700, the stabilizer layer can have a thickness in a range from 0.2 micron to 3.0 microns.

The superconductor tape strands can be used to form a superconductor wire and, optionally, form a superconductor cable. FIG. 11 includes a flow chart for such a process. The process includes wrapping superconductor tape strands around a wire former at block 922. FIG. 12 includes a cross-sectional view of a partially completed superconductor wire 1000 that includes a wire former 1020 and superconductor tape strands 1030. The wire former 1020 can include copper, a copper alloy, a copper composite, or a LTS material, such as Nb—Ti, Nb₃Sn, or the like. The cross-sectional shape of the wire former 1020 can be circular (as illustrated in FIG. 12), rectangular (including a square), hexagonal, elliptical, or the like. The width of the wire former 1020 can be in a range from 0.5 mm to 1.2 mm. When the wire former 1020 has a circular cross-sectional shape, the width is the diameter of the wire former 1020. In an embodiment, the wire former 1020 can be a Cu wire. In the same or different embodiment, the wire former 1020 can correspond to any wire size from American Wire Gauge (AWG) 10 to AWG 26.

The superconductor tape strands 1030 can have any of the configurations as previously described with respect to the superconductor tape strand 700. As compared to each other, the superconductor tape strands 1030 can have the same composition (same layers and films and materials for the layers and films) or different compositions. For example, two different strands 1030 can have different materials for the substrates 220, the superconductor films 344, or the stabilizer layers 868. The strands 1030 have a helical shape after they are wrapped around the wire former 1020. The combination of the wire former 1020 and the strands 1030 have a conductive diameter 1032 in a range from 1 mm to 3 mm. As more superconductor tape strands are used, for example, 40 strands, the conductive diameter 1032 can reach approximately 6 mm. The superconductor wire 1000 can have a predominantly circular cross section (illustrated in FIG. 12) or can have a non-circular cross section.

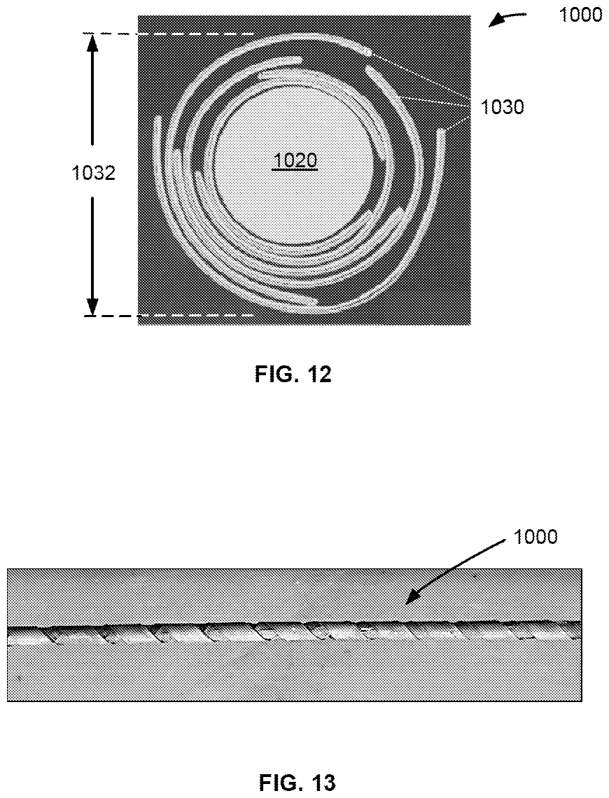

FIG. 13 includes an image of the superconductor wire 1000 in straight form before a protective coating is formed around the superconductor tape strands. When in straight form, the superconductor wire 1000 has an overall length that lies along a straight line.

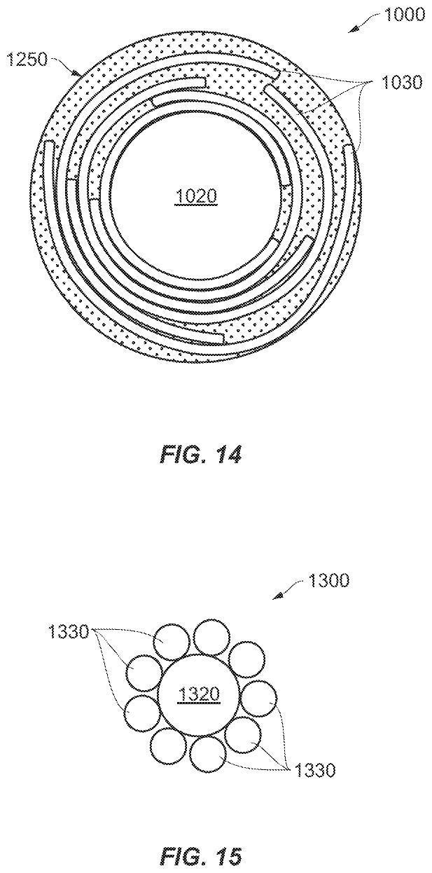

The process further includes forming a protective coating around the superconductor tape strands and wire former at block 924 in FIG. 11. FIG. 14 includes a cross-sectional view of the superconducting wire 1000 after forming the protective coating 1250 around the superconductor tape strands 1030 and the wire former 1020. The protective coating 1250 provides electrical insulating between the superconductor strand tapes 1030 and the environment on the opposite side of protective coating 1250. Thus, the protective coating 1250 can be an electrically insulation media. The protective coating 1250 can also help keep the superconductor tape strands 1030 in place, so that the strands 1030 do not move when the superconductor wire 1000 is installed or used. In the same or different embodiment, the protective coating 1250 can be a polyepoxide (epoxy), a polysiloxane (silicone), a polyolefin, or a suitable electrically insulating polymer for use at a cryogenic temperature. The polyolefin may not be fluorinated or may be a partly or completely fluorinated polyolefin, such as polytetrafluoroethylene or fluorinated ethylene propylene. The protective coating 1250 can be impregnated into the wire, or the protective coating 1250 could be a shrink tube. At this point in the process, the superconductor wire 1000 is substantially completed.

A decision can be made whether the superconductor wire 1000 will be used in making a superconductor cable at decision diamond 932 in FIG. 11. If a superconductor cable is not being made (“No” branch from diamond 932), terminals can be connected to opposite ends of the superconductor wire 1000. The terminals can be connected before or after the protective coating 1250 is formed.

If a superconductor cable is to be formed (“Yes” branch from decision diamond 932), the process can include wrapping superconductor wires around a cable former at block 942 in FIG. 11. FIG. 15 illustrates a cross-sectional view of a superconductor cable 1300 that includes superconductor wires 1330 wrapped around a cable former 1320. The cable former 1320 can include any of the cross-sectional shapes as previously described with respect to the wire former 1020. The width of the cable former 1320 can be in a range from 1.0 mm to 3.0 mm. In an implementation, a cable former 1320 may have a diameter no less than the largest conductive diameter of the superconductor wires that make up the cable. Thus, the cable former 1320 may have a diameter of 6 mm, and potentially larger. When the cable former 1320 has a circular cross-sectional shape, the width is the diameter of the cable former.

The superconductor wires 1330 can have any of the configurations as previously described for the superconductor wire 1000. As compared to each other, the superconductor wires 1330 can have the same composition (same layers and films and materials for the layers and films) or different compositions. The wires 1330 have a helical shape after they are wrapped around the cable former 1320. In another embodiment, the cable former 1320 is not required. The superconductor wires 1330 can be twisted around each other in a helical manner.

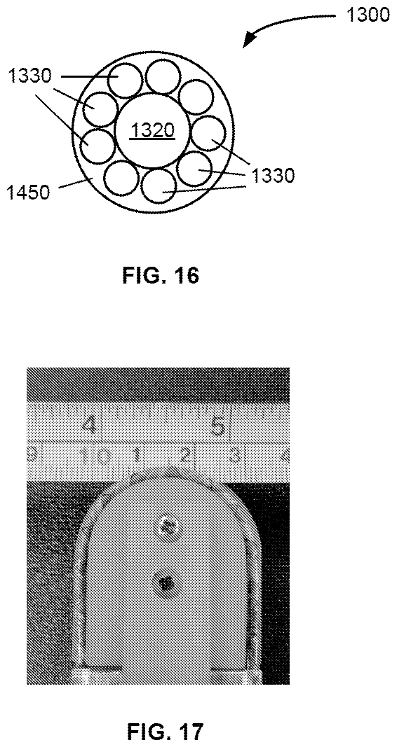

The process can further include forming a protective coating around the superconductor wires at block 944 in FIG. 11. FIG. 16 includes a cross-sectional view of the superconductor cable 1300 after a protective coating 1450 is formed around the superconductor wires 1330 and the cable former 1320. As previously described, the cable former 1320 may or may not be present. The protective coating 1450 can help keep the superconductor wires 1330 in place, so that the wires 1330 do not move when the superconductor cable 1300 is installed or used. In the same or different embodiment, the protective coating 1450 can be a polyepoxide (epoxy), a polysiloxane (silicone), a polyolefin, or a suitable electrically insulating polymer for use at a cryogenic temperature. The polyolefin may not be fluorinated or may be a partly or completely fluorinated polyolefin, such as polytetrafluoroethylene or fluorinated ethylene propylene. The protective coating 1450 can be impregnated into the wire, or the protective coating 1450 could be a shrink tube. Terminals can be connected to opposite ends of the superconductor cable 1300. The terminals can be connected before or after the protective coating 1450 is formed.

The superconductor wires and superconductor cables provide many benefits and allow previously unattainable performance to be achieved. A thicker superconductor film can be used. The thickness of the stabilizer layer 868 can be selected, so that the neutral plane within the superconductor tape strand 700 is closer to or within the superconductor film 344. Such a tape architecture reduces bending strains when the superconductor wire is bent into small diameters. A relatively thinner substrate 220 is better suited for wrapping around a smaller width (e.g., a smaller diameter) of wire former. As compared to conventional strands, a greater number of the novel strands described herein may be used for a particular conductor diameter of superconductor wire. For example, 4 to 40 superconductor tape strands can be used and result in a superconductor wire having a conductor diameter of 1 mm to 6 mm.

The superconductor wires described herein exhibit unexpectedly good tolerance to bend strain. The superconductor wires allow for a bend radius less than 30 mm, which is less than lowest minimum bend radius reported for conventional superconductor wires actually made. The superconductor wires can achieve a bend radius in a range from 10 mm to 25 mm or from 15 mm to 20 mm and still achieve I_{c} retention of at least 70%. A bend radius of 15 mm is used for magnets based on canted cosine theta (CCT) design to achieve a high dipole transfer function. Superconductor wires with a high Jₑ in high magnetic fields at a bend radius of 15 mm are also needed for magnets based on Conductor on Molded Barrel (COMB) design. Thus, the superconductor wires described herein can be used for such applications.

The superconductor wires described herein have unexpectedly good electrical characteristics. A superconductor wire having a conductor diameter no greater than 4 mm can exhibit a Jₑ of at least 600 A/mm² when at a temperature of 4.2 K and exposed to an applied magnetic field of 20 T. Such a high Jₑ can be achieved even when the superconductor wire has a conductor diameter in a range from 1.15 mm to 2.95 mm. Even within this range of conductor diameters, Jₑ can reach 2700 A/mm² and higher. When at a temperature of 4.2 K and exposed to an applied magnetic field of 20 T, the superconductor wire can exhibit Jₑ in a range of 600 A/mm² to 2700 A/mm², 700 A/mm² to 2700 A/mm², 800 A/mm² to 2700 A/mm², or 1000 A/mm² to 2700 A/mm².

In addition to Jₑ, the superconductor wires have high I_{c} per total width. The total width is obtained by summing of the widths of the superconductor tape strands within the superconductor wire. For example, if a superconductor wire has 4 superconductor tape strands each having a width of 2 mm, the total width is 4×2 mm, or 8 mm. In practice, more or fewer stands or strands of different widths can be used in a superconductor wire. A superconductor wire can exhibit a I_{c} per total width of at least 125 A/mm, at least 150 A/mm, or at least 175 A/mm when at a temperature of 4.2 K and exposed to an applied magnetic field of 20 T. I_{c} per total width can reach 275 A/mm and potentially higher. When at a temperature of 4.2 K and exposed to an applied magnetic field of 20 T, the superconductor wire can exhibit I_{c} per total width in a range of 125 A/mm to 275 A/mm, 150 A/mm to 275 A/mm, or 163 A/mm to 275 A/mm.

The superconductor wires have excellent I_{c} retention. FIG. 17 illustrates a superconductor wire at a bend radius of 15 mm. When a superconductor wire is tested at a bend radius of 15 mm, the superconductor wire exhibits at least 70% retention of its critical current. The critical current retention can be at least 80% or at least 90%. The critical current retention can be in a range of 70% to 95% when comparing the superconductor wire at a bend radius of 15 mm to the superconductor wire in straight form.

Many different aspects and embodiments are possible. Some of those aspects and embodiments are described below. After reading this specification, skilled artisans will appreciate that those aspects and embodiments are only illustrative and do not limit the scope of the present invention. Embodiments may be in accordance with any one or more of the embodiments as listed below.

Embodiment 1. A superconductor wire can include a first superconductor tape strand and a second superconductor tape strand. Each of the first superconductor tape strand and the second superconductor tape strand can include a substrate, a buffer stack, a superconductor film, a metal layer, and a stabilizer layer, wherein the metal layer is disposed between the superconductor film and the stabilizer layer. The superconductor wire can have a conductor diameter no greater than 4 mm, and the superconductor wire can exhibit an engineering current density of at least 600 A/mm² when at a temperature of 4.2 K and exposed to an applied magnetic field of 20 T.

Embodiment 2. The superconductor wire of Embodiment 1, wherein the superconductor wire exhibits an engineering current density of at least 700 A/mm² when at a temperature of 4.2 K and exposed to an applied magnetic field of 20 T.

Embodiment 3. A superconductor wire can include a first superconductor tape strand and a second superconductor tape strand. Each of the first superconductor tape strand and the second superconductor tape strand can include a substrate, a buffer stack, a superconductor film, a metal layer, and a stabilizer layer, wherein the metal layer is disposed between the superconductor film and the stabilizer layer. The superconductor wire can exhibit an engineering current density of at least 800 A/mm² when at a temperature of 4.2 K and exposed to an applied magnetic field of 20 T.

Embodiment 4. The superconductor wire of any one of Embodiments 1 to 3, wherein the superconductor wire exhibits a critical current divided by a total width of superconductor tape strands within the superconductor wire of at least 125 A/mm when the superconductor wire is at a temperature of 4.2 K and exposed to an applied magnetic field of 20 T.

Embodiment 5. A superconductor wire can include a first superconductor tape strand and a second superconductor tape strand. Each of the first superconductor tape strand and the second superconductor tape strand can includes a substrate, a buffer stack, a superconductor film, a metal layer, and a stabilizer layer, wherein the metal layer is disposed between the superconductor film and the stabilizer layer. The superconductor wire can exhibit a critical current of at least 125 A/mm of total width of superconductor tape strands when at a temperature of 4.2 K and exposed to an applied magnetic field of 20 T.

Embodiment 6. A superconductor wire can include a first superconductor tape strand and a second superconductor tape strand. Each of the first superconductor tape strand and the second superconductor tape strand can include a substrate; a superconductor film having a thickness of at least 3 microns and including Ba, Cu, and M, wherein M is Hf, Zr, Sn, or a combination thereof, and on an atomic basis, within the superconductor film, (Ba+M)/Cu is greater than 0.72; and a stabilizer layer, wherein the superconductor film is disposed between the substrate and the stabilizer layer.

Embodiment 7. The superconductor wire of any one of Embodiments 1 to 6, wherein the superconductor wire exhibits a critical current retention of at least 70% when at 77 K and exposed to an applied magnetic field of 0 T in a straight form when the superconductor wire is at a bend radius of 15 mm.

Embodiment 8. The superconductor wire of any one of Embodiments 1 to 7, wherein the superconductor wire has a conductor diameter in a range from 1 mm to 3 mm.

Embodiment 9. The superconductor wire of any one of Embodiments 1 to 8, wherein the superconductor wire has a conductor cross-sectional area in a range from 1 mm² to 10 mm².

Embodiment 10. The superconductor wire of any one of Embodiments 1 to 9 further includes a round former, wherein the first superconductor tape strand and the second superconductor tape strand is wound on the round former.

Embodiment 11. The superconductor wire of any one of Embodiments 1 to 9, wherein, when in straight form, the superconductor wire is configured to flow at least 1000 A when at a temperature of 4.2 K and exposed to an applied magnetic field of 20 T.

Embodiment 12. A superconductor cable including the superconductor wire of any one of Embodiments 1 to 11 and another superconductor wire.

Embodiment 13. The superconductor cable of Embodiment 12, wherein the superconductor cable has a diameter in a range from 3 mm to 18 mm.

Embodiment 14. The superconductor cable of Embodiment 12 or 13, wherein the superconductor cable has a cross-sectional area between 6 mm² and 255 mm².

Embodiment 15. A process can include forming a superconductor film over a substrate, wherein the substrate has a first side and a second side opposite the first side, and the superconductor film is closer to the first side than to the second side. The superconductor film can have a thickness of at least 3 microns and includes Ba, Cu, and M, wherein M is Hf, Zr, Sn, or a combination thereof, and on an atomic basis, within the superconductor film, (Ba+M)/Cu is greater than 0.72. The process further includes forming a protective layer over the superconductor film; etching the substrate to reduce a thickness of the substrate; removing the protective layer after removing the portion of the substrate; and forming a stabilizer layer over the superconductor film to form a superconductor tape strand.

### EXAMPLES

Examples described below are provided to demonstrate construction and performance of superconductor wires and superconductor cables. The examples are to aid in the understanding of the concepts described herein and not to limit the scope of the invention as defined in the appended claims.

In the examples below, the superconductor film for the superconductor tapes and superconductor tape strands includes a superconductor film having a modified REBCO composition, where RE is Y, (Ba+Zr)/Cu>0.72, and a thickness of 4 microns. Other REBCO compositions (for example, substituting part or all of Y with Dy or substituting part or all of Zr with Hf) are expected to have similar results. Values for I_{c} and Jₑ are proportional to the thickness of the superconductor film thickness, and thus, a thicker superconductor film will have proportionately greater values for I_{c} and Jₑ, and a thinner superconductor film will have proportionately smaller values for I_{c} and

Superconductor tapes are fabricated with the superconductor film as described in this Examples section, and thus, have the previously described modified REBCO composition and thickness. The substrate is electrochemically etched to achieve a tape thickness of approximately 22 μm. The superconductor tapes are slit into superconductor tape strands having approximately 2 mm widths. Silver (the metal layer 756) and copper (the stabilizer layer 868) are deposited to produce the symmetric architecture, wherein the superconductor film is positioned near or along the neutral plane.

### Example 1

Example 1 demonstrates I_{c} that can be achieved by a superconductor wire and the superconductor wire's associated lift factor and alpha value (a), and how such information can be used to predict I_{c} at different applied magnetic fields.

Superconductor tape strands were prepared as previously described in this Examples Section. Four of the superconductor tape strands were wound on 18 AWG former (1.02 mm diameter). The total tape width of all strands was 8 mm. FIG. 13 includes a photograph of the superconductor wire 1000. The conductor diameter of the superconductor wire 1000 was 1.51 mm.

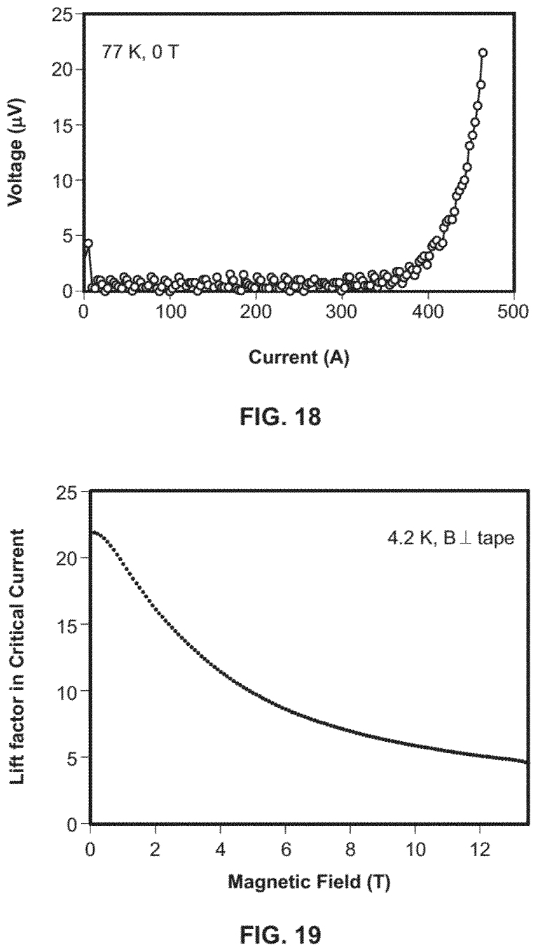

FIG. 18 includes current-voltage characteristics for the superconductor wire when the superconductor wire was at a bend radius of 15 mm. The superconductor wire exhibited I_{c} of 420 A at 77 K and an applied magnetic field of 0 T.

FIG. 19 has a plot of lift factor in I_{c} as a function of applied magnetic field that was generated for the previously described four individual strands of the superconductor wire, where a magnetic field up to 13 T was applied perpendicular to a tape plane (the plane defined by the length and width of the superconductor tape strands). The lift factor in I_{c} is defined as the ratio of (1) I_{c} for a superconductor tape strand at 4.2 K and exposed to a magnetic field applied perpendicular to a tape plane to (2) the I_{c} for the superconductor tape strand at 77 K and an applied magnetic field of 0 T. The data in FIG. 19 reveals an alpha value (a) of 0.759. The alpha value is the power-law exponent relating the I_{c} (or lift factor in I_{c}) to the magnetic field (B) as I_{c}≈B^{-α}. Based on the alpha value, the corresponding lift factor in I_{c} expected at 4.2 K and an applied magnetic field 30 T (applied perpendicular to the tape strand) is 2.55. The predicted I_{c} for the superconductor wire is 1070 A when the superconductor wire is at 4.2 K and exposed to an applied magnetic field of 30 T.

### Example 2

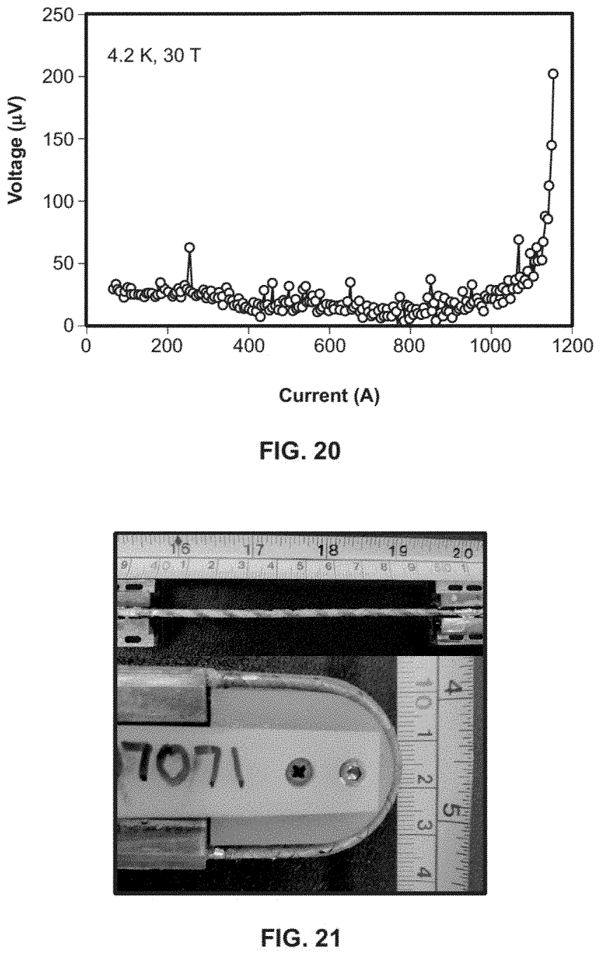

Example 2 demonstrates that the predicted I_{c} at a magnetic field of 30 T in Example 1 is achieved in practice. The superconductor wire as described in Example 1 when at a bend radius of 15 mm was tested at 4.2 K and exposed to an applied magnetic field of 30 T. The data is shown in FIG. 20. I_{c} for the superconductor wire was measured to be 1070 A when the superconductor wire was at 4.2 K and exposed to an applied magnetic field of 30 T. Thus, Jₑ is 597 A/mm².

The predicted I_{c} (in Example 1) was based on lift factor in I_{c} of the superconductor tape strands used in the superconductor wire as described previously. Accordingly, the lift factor in I_{c} for superconductor tape strands used in a superconductor wire can be used to determine the I_{c} of the superconductor wire in high magnetic fields. The lift factor in I_{c} of superconductor tape strands used in the superconductor wire is at 4.2 K and exposed to an applied magnetic field of 20 T is projected to be 3.46 from the alpha value obtained in data shown in FIG. 19. Therefore, I_{c} of the superconductor wire at 4.2 K and exposed to an applied magnetic field of 20 T will be 1455 A, and Jₑ will be 812 A/mm². The Jₑ value is substantially higher and unexpectedly better than the best Jₑ of 586 A/mm² achieved in conventional superconductor wires made so far, as reported in technical journal articles.

### Example 3

Example 3 demonstrates that another superconductor wire with a different conductive diameter also has unexpectedly good I_{c} and Jₑ. A superconductor wire was fabricated using four superconductor tape strands and had a conductor diameter of 1.49 mm. The superconductor wire was bent to a 15 mm radius and exhibited a I_{c} of 506 A at 77 K and an applied magnetic field of 0 T. The lift factor in I_{c} of the superconductor tape strands at 4.2 K and exposed to an applied magnetic field of 20 T was 3.88. Thus, the I_{c} of the superconductor wire at 4.2 K and exposed to an applied magnetic field of 20 T is predicted to be 1960 A at a bend radius of 15 mm. The Jₑ of the superconductor wire at 4.2 K and exposed to an applied magnetic field of 20 T is predicted to be 1126 A/mm² at a bend radius of 15 mm.

### Example 4

Example 4 demonstrates that another superconductor wires with a different conductive diameter has unexpectedly good I_{c} and Jₑ. A superconductor wire was fabricated on 0.81 mm copper alloy former using 12 symmetric tape strands and had a conductor diameter of 2.52 mm. The widths of the individual tape strands used in the wire were 1.5 mm, 1.5 mm, 2 mm, 2 mm, 2.3 mm, 2.3 mm, 2.6 mm, 2.6 mm, 2.6 mm, 2.6 mm, 2.6 mm, and 2.6 mm. The total width of the tape strands was 27.2 mm. Photographs of the wire tested in a straight form and at a bend radius of 15 mm are shown in FIG. 21.

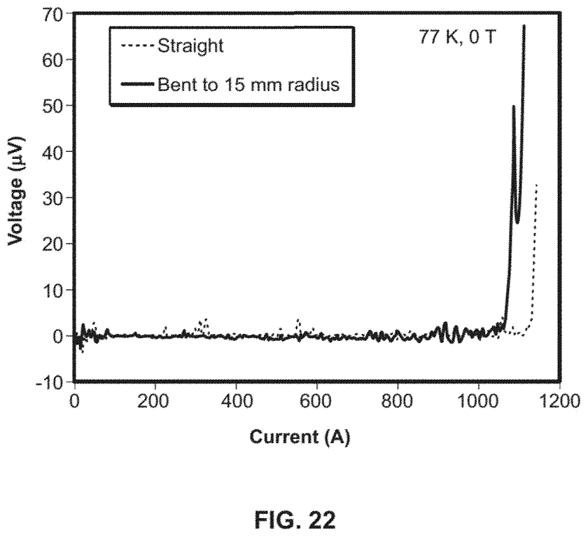

As seen in FIG. 22, the I_{c} of the 2.52 mm diameter wire in straight form was 1140 A at 77 K, 0 T. The I_{c} of the wire when bent to 15 mm radius was 1090 A at 77 K, 0 T. This corresponds to I_{c} retention of 95% when bent to 15 mm radius. The lift factor in I_{c} of tape strands used in wire was 4.72 at 4.2 K and exposed to an applied magnetic field of 20 T. For the 2.52 mm superconductor wire at a bend radius of 15 mm at 4.2 K and exposed to an applied magnetic field of 20 T, I_{c} will be 5140 A corresponding to a Jₑ of 1030 A/mm².

### Further Examples

Simulations were performed to obtain I_{c} and Jₑ for superconductor wires at a 15 mm radius bend. Preliminary simulations for superconductor tape strands are used, where the strands have I_{c} of 600 A, 750 A, 900 A, 1100 A, or 1300 A when the strands are at 4.2° K and exposed to a magnetic field of 20 T applied to the tape plane of the strands. Architectures for the superconductor wires are provided in the second though fourth columns of Table 1 below. Table 2 has the widths of the strands, called “Layer #” in Table 2, where Layer #1 is the strand that is wrapped closest to the wire former, and Layer #30 is the strand wrapped farthest from the wire former. Each of the wire formers used to make the superconductor wires in Table 1 has a diameter of 0.7 mm.

TABLE 1

| I_{c} of tape strand | # tape | Total strand | Wire | Wire cross | | | I_{c} of wire per total |
|---|---|---|---|---|---|---|---|
| @ 4.2 K, 20 T | strands | width in wire | diameter | sectional area | I_{c} of wire @ 4.2 K, | Jₑ of wire at 4.2 K, | strand width |
| (A/4 mm) | in wire | (mm) | (mm) | (mm²) | 20 T (A) | 20 T (A/mm²) | @ 4.2 K, 20 T (A/mm) |
| 600 | 4 | 7 | 1.15 | 1.04 | 893 | 859 | 128 |
| 750 | 4 | 7 | 1.15 | 1.04 | 1,116 | 1,074 | 159 |
| 900 | 4 | 7 | 1.15 | 1.04 | 1,339 | 1,289 | 191 |
| 1100 | 4 | 7 | 1.15 | 1.04 | 1,636 | 1,575 | 234 |
| 1300 | 4 | 7 | 1.15 | 1.04 | 1,934 | 1,862 | 276 |
| 600 | 9 | 19.4 | 1.71 | 2.30 | 2,474 | 1,074 | 128 |
| 750 | 9 | 19.4 | 1.71 | 2.30 | 3,092 | 1,342 | 159 |
| 900 | 9 | 19.4 | 1.71 | 2.30 | 3,710 | 1,611 | 191 |
| 1100 | 9 | 19.4 | 1.71 | 2.30 | 4,535 | 1,969 | 234 |
| 1300 | 9 | 19.4 | 1.71 | 2.30 | 5,359 | 2,327 | 276 |
| 600 | 12 | 29.3 | 2.05 | 3.30 | 3,736 | 1,132 | 128 |
| 750 | 12 | 29.3 | 2.05 | 3.30 | 4,670 | 1,415 | 159 |
| 900 | 12 | 29.3 | 2.05 | 3.30 | 5,604 | 1,698 | 191 |
| 1100 | 12 | 29.3 | 2.05 | 3.30 | 6,849 | 2,075 | 234 |
| 1300 | 12 | 29.3 | 2.05 | 3.30 | 8,094 | 2,452 | 276 |
| 600 | 15 | 41.3 | 2.39 | 4.48 | 5,266 | 1,176 | 128 |
| 750 | 15 | 41.3 | 2.39 | 4.48 | 6,582 | 1,470 | 159 |
| 900 | 15 | 41.3 | 2.39 | 4.48 | 7,899 | 1,764 | 191 |
| 1100 | 15 | 41.3 | 2.39 | 4.48 | 9,654 | 2,156 | 234 |
| 1300 | 15 | 41.3 | 2.39 | 4.48 | 11,409 | 2,548 | 276 |
| 600 | 20 | 65.7 | 2.95 | 6.83 | 8,377 | 1,226 | 128 |
| 750 | 20 | 65.7 | 2.95 | 6.83 | 10,471 | 1,532 | 159 |
| 900 | 20 | 65.7 | 2.95 | 6.83 | 12,565 | 1,838 | 191 |
| 1100 | 20 | 65.7 | 2.95 | 6.83 | 15,357 | 2,247 | 234 |
| 1300 | 20 | 65.7 | 2.95 | 6.83 | 18,150 | 2,655 | 276 |

TABLE 2

| Layer # | Tape width (mm) |
|---|---|
| 1 | 1.5 |
| 2 | 1.5 |
| 3 | 2 |
| 4 | 2 |
| 5 | 2.3 |
| 6 | 2.3 |
| 7 | 2.6 |
| 8 | 2.6 |
| 9 | 2.6 |
| 10 | 3.3 |
| 11 | 3.3 |
| 12 | 3.3 |
| 13 | 4 |
| 14 | 4 |
| 15 | 4 |
| 16 | 4.6 |
| 17 | 4.6 |
| 18 | 4.6 |
| 19 | 5.3 |
| 20 | 5.3 |
| 21 | 5.3 |
| 22 | 6 |
| 23 | 6 |
| 24 | 6 |
| 25 | 6.6 |
| 26 | 6.6 |
| 27 | 6.6 |
| 28 | 7.3 |
| 29 | 7.3 |
| 30 | 7.3 |

For some or all of the layers, the tape width per layer could be for a single tape or a sum for two tapes. For instance, 4.6 mm width could be two tapes of 2.3 mm wide each, 6.6 mm could be two tapes of 3.3 mm wide each, 6 mm could be a 4 mm+2 mm tape, and 7.3 mm could be 4 mm+3.3 mm. The foregoing examples are exemplary and not intended to limit the scope of the invention as defined in the appended claims.

The values for I_{c}, Jₑ, and I_{c} of wire per total strand width are based on the I_{c} of the tape strand (first column), the superconductor wire architecture (second to fourth columns), and I_{c} retention of 85% for a 15 mm radius bend of the superconductor wires.

The electrical properties are very good. Referring to the sixth column of Table 1, I_{c} for the superconductor wires when at 4.2 K and exposed to a magnetic field of 20 T applied to the lengths of the superconductor wires is in a range from 893 A to 36,105 A. For each level of I_{c} of the tape strands (first column, 600 A, 750 A, 900 A, 1100 A, and 1300 A), as the total strand width in the superconductor wires increase, so does I_{c}. Jₑ for the superconductor wires (seventh column of Table 1) is obtained by dividing I_{c} of the wire (sixth column) by the wire cross-sectional area (fifth column). Jₑ is in a range of 859 A/mm² to 2768 A/mm². These values are unexpectedly good because the closest reported value for Jₑ for a superconductor wire at a 15 mm radius bend is 586 A/mm². I_{c} per total strand width is obtained by taking I_{c} of the wire (fifth column) and dividing it by the total strand width in the superconductor wire (third column). I_{c} per total strand width is in a range from 128 A/mm to 276 A/mm.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A superconductor wire, comprising:
a first superconductor tape strand and a second superconductor tape strand, wherein each of the first superconductor tape strand and the second superconductor tape strand includes:
a substrate;
a buffer stack;
a superconductor film;
a metal layer; and
a stabilizer layer, wherein the metal layer is disposed between the superconductor film and the stabilizer layer,
wherein the superconductor wire has a conductor diameter no greater than 4 mm, and the superconductor wire exhibits an engineering current density of at least 600 A/mm² when at 4.2 K and exposed to an applied magnetic field of 20 T.

2. The superconductor wire of claim 1, wherein the engineering current density is at least 700 A/mm² when at 4.2 K and exposed to the applied magnetic field of 20 T.

3. The superconductor wire of claim 1, wherein the superconductor film:
the superconductor film is a rare earth-barium-copper-oxide including Ba, Cu, and M, wherein:
M is Hf, Zr, Sn, or a combination thereof, and
on an atomic basis, within the superconductor film, (Ba+M)/Cu is greater than 0.72.

4. The superconductor wire of claim 3, wherein the substrate has a thickness in a range from 10 microns to 25 microns.

5. The superconductor wire of claim 4, wherein the stabilizer layer has a thickness along a superconductor-side of the first superconductor tape strand or the second superconductor tape strand in a range from 12 microns to 50 microns.

6. The superconductor wire of claim 3, further comprising a wire former having a diameter in a range from 0.5 mm to 1.1 mm.

7. A superconductor wire, comprising:
a first superconductor tape strand and a second superconductor tape strand, wherein each of the first superconductor tape strand and the second superconductor tape strand includes:
a substrate;
a buffer stack;
a superconductor film;
a metal layer; and
a stabilizer layer, wherein the metal layer is disposed between the superconductor film and the stabilizer layer,
wherein the superconductor wire exhibits an engineering current density of at least 800 A/mm² when at 4.2 K and exposed to an applied magnetic field of 20 T.

8. The superconductor wire of claim 7, wherein the superconductor wire exhibits a critical current retention of at least 70% when at 77 K and exposed to an applied magnetic field of 0 T in a straight form when the superconductor wire is at a bend radius of 15 mm.

9. The superconductor wire of claim 7, wherein the substrate has a thickness in a range from 10 microns to 25 microns.

10. The superconductor wire of claim 9, wherein the superconductor film:
has a thickness of at least 3 microns, and
is a rare earth-barium-copper-oxide including Ba, Cu, and M, wherein:
M is Hf, Zr, Sn, or a combination thereof, and
on an atomic basis, within the superconductor film, (Ba+M)/Cu is greater than 0.72.

11. The superconductor wire of claim 9, further comprising a wire former having a diameter in a range from 0.5 mm to 1.1 mm.

12. The superconductor wire of claim 7, wherein the superconductor wire exhibits a critical current of at least 125 A/mm of total width of superconductor tape strands when at 4.2 K and exposed to an applied magnetic field of 20 T.

13. A superconductor cable, the superconductor cable comprising the superconductor wire of claim 7 and another superconductor wire.

14. The superconductor cable of claim 13, wherein the superconductor cable has a diameter in a range from 3 mm to 18 mm.

15. A superconductor wire, comprising:
a first superconductor tape strand and a second superconductor tape strand, wherein each of the first superconductor tape strand and the second superconductor tape strand includes:
a substrate;
a buffer stack;
a superconductor film;
a metal layer; and
a stabilizer layer, wherein the metal layer is disposed between the superconductor film and the stabilizer layer,
wherein the superconductor wire exhibits a critical current of at least 125 A/mm of total width of superconductor tape strands when at 4.2 K and exposed to an applied magnetic field of 20 T.

16. The superconductor wire of claim 15, wherein the superconductor wire exhibits an engineering current density of at least 700 A/mm² when at 4.2 K and exposed to the applied magnetic field of 20 T.

17. The superconductor wire of claim 15, wherein the superconductor wire has a conductor diameter in a range from 1 mm to 3 mm.

18. The superconductor wire of claim 15, wherein, when in straight form, the superconductor wire is configured to flow at least 1000 A when at 4.2 K and exposed to the applied magnetic field of 20 T.

19. The superconductor wire of claim 15, further comprising a wire former, wherein:
the superconductor film:
the superconductor film is a rare earth-barium-copper-oxide including Ba, Cu, and M, wherein:
M is Hf, Zr, Sn, or a combination thereof, and
on an atomic basis, within the superconductor film, (Ba+M)/Cu is greater than 0.72,
the substrate has a thickness in a range from 10 microns to 25 microns, and
the wire former has a diameter in a range from 0.5 mm to 1.1 mm.

20. The superconductor wire of claim 19, wherein:
the superconductor film has a thickness of at least 3 microns, and
the stabilizer layer has a thickness along a superconductor-side of the first superconductor tape strand or the second superconductor tape strand in a range from 12 microns to 50 microns.
